(19) United States
(12) Patent Application Publication
(10) Pub. No.: US 2024/0159842 A1
(43) Pub. Date: May 16, 2024

(54) CABLE TESTING

(71) Applicant: Southwire Company, LLC, Carrollton, GA (US)

(72) Inventor: Sherif Ibrahim Kamel, Cary, NC (US)

(21) Appl. No.: 18/504,872

(22) Filed: Nov. 8, 2023

Related U.S. Application Data
(60) Provisional application No. 63/383,401, filed on Nov. 11, 2022.

(51) Int. Cl. G01R 31/58

(52) U.S. Cl. CPC G01R 31/58

(57) ABSTRACT

Cable testing may be provided. A first end of a cable may be prepared using stress control tubing and stress relief mastic. Then the first end of the cable may be directly connected to a high voltage supply. The cable may then be tested.

### RELATED APPLICATION

Under provisions of 35 U.S.C. § 119(e), Applicant claims the benefit of U.S. Provisional Application No. 63/383,401 filed Nov. 11, 2022, which is incorporated herein by reference.

### BACKGROUND

A High Voltage (HV) underground cable is a cable used for electric power transmission at a high voltage. A cable includes a conductor and insulation system. Cables are considered to be fully insulated. This means that they have a fully rated insulation system that will comprise insulation, a semiconductor layer, a metallic shield, and a jacket. This is in contrast to an overhead line that may include insulation, but not fully rated for operating voltage (e.g., tree wire). High voltage cables of differing types have a variety of applications in Alternating Current (AC) and Direct Current (DC) power transmission. In all applications, the insulation of the cable must not deteriorate due to the electrical, mechanical, or thermal stresses. The cable system must prevent contact of the high-voltage conductor with other objects or persons, and must contain and control leakage current and electrical stress.

Cable joints and terminals must be designed to control the high-electrical stress to prevent the breakdown of the insulation. Joints may maintain the continuity of electrical cables over long lengths by joining them and thus, enable the transmission of electricity. Cable joints have to fit and be robust enough to withstand factors like adverse weather conditions, current carrying capacity, connection voltage drop, and compatibility of materials.

The cut lengths of high voltage cables may vary from several feet to thousands of feet, with relatively short cables used in apparatus and longer cables run within buildings or as buried cables in an industrial plant or for power distribution and transmission. The longest cut lengths of cable will often be submarine cables under large water bodies for power transmission.

### BRIEF DESCRIPTION OF THE FIGURES

The accompanying drawings, which are incorporated in and constitute a part of this disclosure, illustrate various embodiments of the present disclosure. In the drawings:

FIG. 1 illustrates a cable testing system;

FIG. 2 is a flow chart of a method for providing cable testing;

FIGS. 3A, 3B, 3C, 3D, and 3E illustrate cable end preparation; and

FIG. 4 illustrate cable end preparation.

### DETAILED DESCRIPTION

### Overview

Cable testing may be provided. A first end of a cable may be prepared using stress control tubing and stress relief mastic. Then the first end of the cable may be directly connected to a high voltage supply. The cable may then be tested.

Both the foregoing overview and the following example embodiments are examples and explanatory only, and should not be considered to restrict the disclosure's scope, as described and claimed. Further, features and/or variations may be provided in addition to those set forth herein. For example, embodiments of the disclosure may be directed to various feature combinations and sub-combinations described in the example embodiments.

### Example Embodiments

The following detailed description refers to the accompanying drawings. Wherever possible, the same reference numbers are used in the drawings and the following description to refer to the same or similar elements. While embodiments of the disclosure may be described, modifications, adaptations, and other implementations are possible. For example, substitutions, additions, or modifications may be made to the elements illustrated in the drawings, and the methods described herein may be modified by substituting, reordering, or adding stages to the disclosed methods. Accordingly, the following detailed description does not limit the disclosure. Instead, the proper scope of the disclosure is defined by the appended claims.

High Voltage Direct Current (HVDC) cable electrical testing may include an Alternating Current (AC) withstand test, a Partial Discharge (PD) test, and a HVDC withstand test. For voltage classes lower than 400 kV, for example, water terminations have been used to terminate the cable to perform these tests. At voltages 400 kV and above, water terminations may not exist commercially for the DC testing. Accordingly, the cable must be prepared for use in water terminations to perform the AC and PD testing and then re-prepared/re-adapted for another process of testing.

A conventional process may be to prepare and fit the cable under test with an HV end cap (i.e., a one sided joint) at one end. Then, at the other end of the cable, it may be fitted with a full joint. Furthermore, this full joint may connect the cable under test to lab infrastructure (e.g., a voltage source) via a permanent termination fitted with a cable section to mate with the joint.

This conventional process may require special preparation of the cable ends and significant effort and time for such installation. For example, while the required test duration may be one hour, the conventional process uses the same costly joints installed with the cable in the field, which may be expected to last for 40 years of service life. Further any failure of the cable (e.g., near or within the joints or the termination) may require a complete replacement of the failed components that constitutes even more cost and delay. Moreover, the conventional process of installing the joints may require many hours and at least two operators in addition to specialized equipment and tools. Accordingly, embodiments of the disclosure may provide a process to test cables without use of time consuming and costly joints. Furthermore, embodiments of the disclosure may provide a process to test cables without use of a permanent termination fitted with the cable section to mate with the joint.

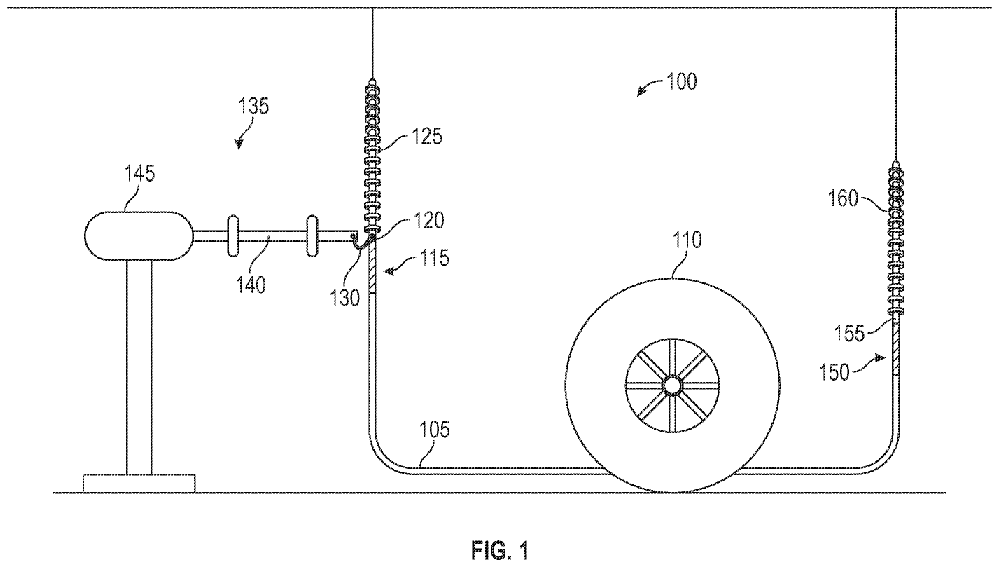

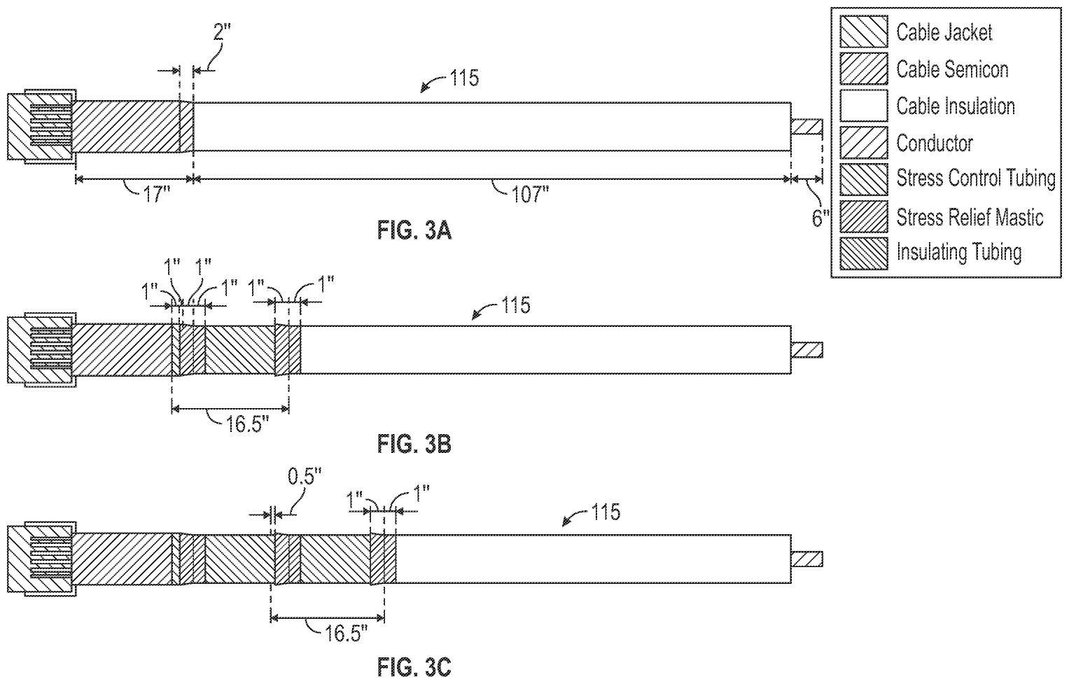

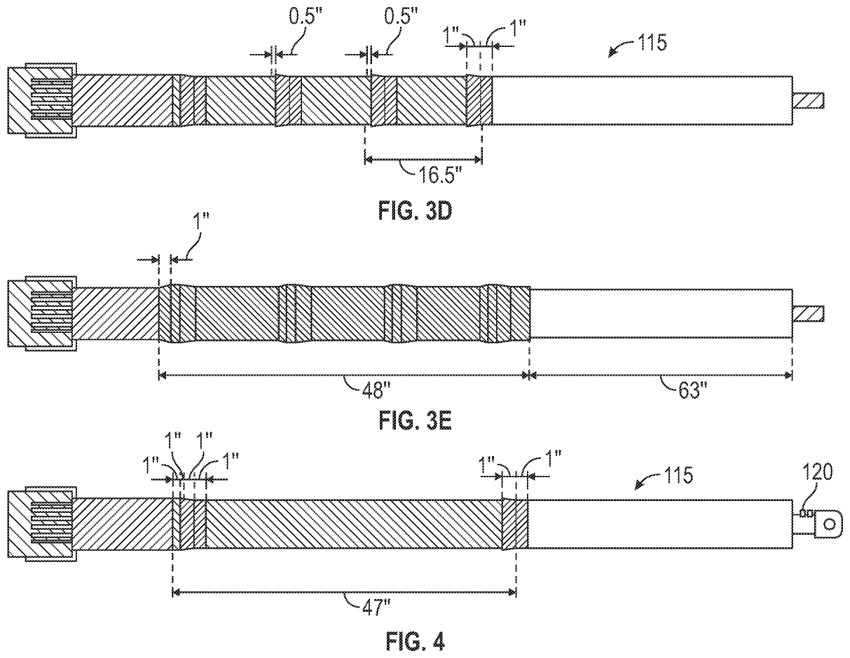

FIG. 1 illustrates a cable testing system 100. As shown in FIG. 1, cable testing system 100 may comprise a cable 105 disposed on a reel 110. For example, cable 105 may comprise a High Voltage Direct Current (HVDC) cable. Cable 105 may comprise a first end 115. The preparation of first end 115 will be described in greater detail below with respect to FIG. 3A, FIG. 3B, FIG. 3C, FIG. 3D, FIG. 3E, and FIG. 4. A first connector 120 may be connected to a conductor in cable 105 at first end 115. First connector 120 may be electrically conductive and may also be connected to a first insulator 125. Cable testing system 100 may be contained within a testing room and first insulator 125 may be suspended from a ceiling of the testing room. Cable 105 may suspend from first insulator 125 at first end 115 of cable 105.

A jumper 130 may be electrically connected to first connector 120 and/or the conductor in cable 105 at first end 115 and may electrically connect the conductor in cable 105 to a high voltage supply 135. A protection resistor 140 may be placed between the conductor in cable 105 and a voltage source 145. Protection resistor 140 may comprise, but is not limited to, 750 kn. Voltage source 145 may supply a Direct Current (DC) voltage. The voltage supplied by voltage source 145 should be of appropriate rating for the test level. Accordingly, high voltage supply 135 may energize cable 105 during a test of cable 105.

Cable 105 may comprise a second end 150. The preparation of second end 150 will be described in greater detail below with respect to FIG. 3A, FIG. 3B, FIG. 3C, FIG. 3D, FIG. 3E, and FIG. 4. Second end 150 may be prepared in a way similar to first end 115. A second connector 155 may be connected to the conductor in cable 105 at second end 150. Second connector 155 may be electrically conductive and may also be connected to a second insulator 160. As stated above, cable testing system 100 may be contained within the testing room. Second insulator 160 may be suspended from the ceiling of the testing room. Accordingly, cable 105 may suspend from second insulator 160 at second end 150 of cable 105. Accordingly, second end 150 of cable 105 may be electrically isolated. First end 115 and second end 150 of cable 105 may be used, for example, for a one hour HVDC routine testing of cable 105 and may not be designed for general purpose use. Notwithstanding, embodiments of the disclosure may include first end 115 and/or second end 150 prepared with or without insulating tubing.

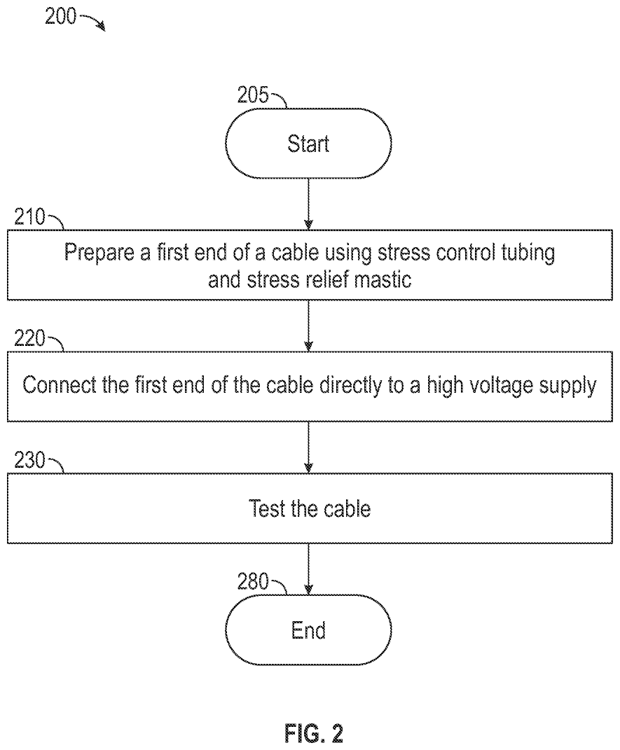

FIG. 2 is a flow chart setting forth the general stages involved in a method 200 consistent with embodiments of the disclosure for providing cable testing. Method 200 may be implemented using cable testing system 100 as described in more detail above with respect to FIG. 1. Ways to implement the stages of method 200 will be described in greater detail below.

Method 200 may begin at starting block 205 and proceed to stage 210 where first end 115 of cable 105 may be prepared using stress control tubing and stress relief mastic. As stated above, second end 150 may be prepared and suspended in a way similar to first end 115 prior to testing cable 105. For example, embodiments of the disclosure may use a combination of heat shrink tubing and stress relief mastic placed strategically on cable 105 in place of the two joints and the permanent termination as described above. This arrangement may be adequate for the testing duration needed (e.g., the 1 hour withstand requirement of the HVDC routine test of the cable). The cable preparation according to embodiments of the disclosure may require less time (e.g., less than one hour) and may not require more than one operator. According to embodiments of the disclosure, the terminations (e.g., cable ends) may be sacrificial and not reused, but the cost may be a small fraction of the aforementioned conventional process. In case of failure of the cable or a termination, the relevant end of the cable may be discarded and reprepared.

FIG. 3A illustrates first end 115 where a cable jacket, a cable semiconductor layer, and a cable insulation layer may be removed for an end of cable 105 exposing a portion of the conductor at the end of cable 105. A chamfer may be made in the semiconductor layer where the semiconductor layer and the cable insulation layer meet. As shown in FIG. 3B, relief mastic may be disposed where the semiconductor layer and the cable insulation layer meet. Stress control tubing may be placed over this relief mastic and continue over the exposed cable insulation layer. More relief mastic may be disposed where the stress control tubing and the cable insulation layer meet. This process may be repeated for a second stress control tubing as illustrated in FIG. 3C. Furthermore, this process may be repeated for a third stress control tubing as illustrated in FIG. 3D. Embodiments of the disclosure may use any number of stress control tubing and is not limited to three. Insulating tubing may be placed over the stress control tubing as shown in FIG. 3E. Both the stress control tubing and the insulating tubing may comprise heat shrink materials and may be shrunk to fit using a torch for example. Furthermore, embodiments of the disclosure may include first end 115 and/or second end second end 150 prepared with or without insulating tubing.

FIG. 4 illustrates an embodiment of the disclosure of first end 115 where one long stress control tubing may be used rather than multiple stress control tubing as shown in FIG. 3D. The dimensions shown in FIG. 3A, FIG. 3B, FIG. 3C, FIG. 3D, FIG. 3E, and FIG. 4 are examples and other dimensions may be used consistent with embodiments of the disclosure. For example, the dimensions may be +/−10% of the values shown in in FIG. 3A, FIG. 3B, FIG. 3C, FIG. 3D, FIG. 3E, and FIG. 4. Furthermore, these dimensions may be used for 400 kV voltage cable classes and other dimensions may be used for other cable voltage classes consistent with embodiments of the disclosure. First end 115 and second end 150 may comprise the embodiments shown in FIG. 3D (e.g., multiple stress control tubing) or the embodiments shown in FIG. 4 (e.g., one stress control tubing). Notwithstanding either of the embodiments of FIG. 3D and FIG. 4 may include insulating tubing as shown in FIG. 3E. The embodiments shown in FIG. 3A, FIG. 3B, FIG. 3C, FIG. 3D, FIG. 3E, and FIG. 4 may provide electrical stress relief, for example, by stretching the electrical stress at first end 115 and/or second end 150.

From stage 210, where first end 115 of cable 105 is prepared using stress control tubing and stress relief mastic, method 200 may advance to stage 220 where first end 115 of cable 105 may be directly connected to high voltage supply 135. For example, cable 105 may be connected to high voltage supply 135 without the expense of using joints or a permanent termination.

First connector 120 may be connected to the conductor in cable 105 at first end 115. First connector 120 may be electrically conductive and may also be connected to first insulator 125. Cable 105 may suspend from first insulator 125 at first end 115 of cable 105.

Jumper 130 may be electrically connected to first connector 120 and/or the conductor in cable 105 at first end 115 and may electrically connect the conductor in cable 105 to high voltage supply 135. Protection resistor 140 may be placed between the conductor in cable 105 and voltage source 145. Accordingly, high voltage supply 135 may energize cable 105 during test of cable 105.

Cable 105 may also comprise second end 150. Second end 150 may be prepared in a way similar to first end 115. Second connector 155 may be connected to the conductor in cable 105 at second end 150. Second connector 155 may be electrically conductive and may also be connected to second insulator 160. Second insulator 160 may be suspended from the ceiling of the testing room. Accordingly, cable 105 may suspend from second insulator 160 at second end 150 of cable 105. Accordingly, second end 150 of cable 105 may be electrically isolated.

Once first end 115 of cable 105 is directly connected to high voltage supply 135 in stage 220, method 200 may continue to stage 230 where cable 105 may be tested. For example, after cable 105 is manufactured, it may be placed on reel 110. Reel 110 may then be sent to the room comprising cable testing system 100. Testing cable 105 may comprise, but not limited to, performing at least one of an Alternating Current (AC) withstand test, a partial discharge test, and a High Voltage Direct Current (HVDC) withstand test. After testing cable 105, first end 115 and second end 150 may be removed from cable 105. Accordingly, cable 105 may be tested without the expense of using joints or a permanent termination. The expense in preparing first end 115 and second end 150 and the loss of first end 115 and second end 150 may be significantly less than the expense of using joints and the permanent termination. Once cable 105 is tested in stage 230, method 200 may then end at stage 240.

While the specification includes examples, the disclosure's scope is indicated by the following claims. Furthermore, while the specification has been described in language specific to structural features and/or methodological acts, the claims are not limited to the features or acts described above. Rather, the specific features and acts described above are disclosed as example for embodiments of the disclosure.

What is claimed is:

1. A method comprising:
preparing a first end of a cable using stress control tubing and stress relief mastic;
connecting the first end of the cable directly to a high voltage supply; and
testing the cable.

2. The method of claim 1, wherein preparing the first end of a cable further comprises using insulating tubing.

3. The method of claim 1, wherein the high voltage supply provides a Direct Current (DC) voltage.

4. The method of claim 1, wherein testing the cable comprises performing a High Voltage Direct Current (HVDC) withstand test.

5. The method of claim 1, wherein the cable is disposed on a reel.

6. The method of claim 1, wherein the cable comprises a High Voltage Direct Current (HVDC) cable.

7. The method of claim 1, wherein connecting the first end of the cable directly to the high voltage supply comprises connecting the first end of the cable directly to the high voltage supply without using a joint.

8. The method of claim 1, wherein connecting the first end of the cable directly to the high voltage supply comprises connecting the first end of the cable directly to the high voltage supply without using a permanent termination.

9. The method of claim 1, further comprising removing the first end from the cable after testing the cable.

10. The method of claim 1, wherein connecting the first end of the cable directly to the high voltage supply comprises suspending the first end of the cable from a first insulator.

11. The method of claim 10, wherein connecting the first end of the cable directly to the high voltage supply comprises electrically connecting a conductor at the first end of the cable to the high voltage supply via a jumper.

12. The method of claim 1, further comprising:
preparing a second end of the cable using stress control tubing and stress relief mastic; and
electrically isolating the second end of the cable.

13. The method of claim 12, wherein preparing the second end of the cable further comprises using insulating tubing.

14. The method of claim 12, wherein electrically isolating the second end of the cable comprises suspending the second end of the cable from a second insulator.

15. The method of claim 12, wherein electrically isolating the second end of the cable comprises electrically isolating the second end of the cable without using a joint.

16. The method of claim 12, further comprising removing the second end from the cable after testing the cable.

17. A method comprising:
preparing a first end of a cable using stress control tubing and stress relief mastic wherein the cable comprises a High Voltage Direct Current (HVDC) cable;
connecting the first end of the cable directly to a high voltage supply wherein the high voltage supply provides a Direct Current (DC) voltage wherein connecting the first end of the cable directly to the high voltage supply comprises connecting the first end of the cable directly to the high voltage supply without using a joint; and
testing the cable.

18. The method of claim 17, wherein connecting the first end of the cable directly to the high voltage supply comprises connecting the first end of the cable directly to the high voltage supply without using a permanent (or additional) termination.

19. The method of claim 17, wherein connecting the first end of the cable directly to the high voltage supply comprises:
suspending the first end of the cable from a first insulator; and
electrically connecting a conductor at the first end of the cable to the high voltage supply via a jumper.

20. An apparatus comprising:
a first end of a cable prepared using stress control tubing and stress relief mastic wherein the cable comprises a High Voltage Direct Current (HVDC) cable; and
a high voltage supply directly connected to the first end of the cable for testing of the cable wherein the high voltage supply provides a Direct Current (DC) voltage wherein connecting the first end of the cable directly to the high voltage supply comprises connecting the first end of the cable directly to the high voltage supply without using a joint.
